(19) United States
(12) Patent Application Publication
(10) Pub. No.: US 2026/0246476 A1
(43) Pub. Date: Aug. 20, 2026

(54) Digital-to-analog conversion apparatus and digital-to-analog conversion method having signal calibration mechanism

(71) Applicant: REALTEK SEMICONDUCTOR CORPORATION, Hsinchu (TW)

(72) Inventors: Hsuan-Ting HO, Hsinchu (TW); Shih-Hsiung HUANG, Hsinchu (TW); Liang-Wei HUANG, Hsinchu (TW)

(21) Appl. No.: 19/460,723

(22) Filed: Jan. 27, 2026

(30) Foreign Application Priority Data
Feb. 14, 2025 (TW) 114105594

(51) Int. Cl. H03M 1/10; H03M 1/66

(52) U.S. Cl. CPC H03M 1/1009; H03M 1/66

(57) ABSTRACT

A digital-to-analog conversion apparatus is disclosed. A digital-to-analog conversion circuit performs conversion according to signal feeding related to an input digital signal including an odd part that has a rounding error and an even part to generate an output analog signal. An echo transmission circuit processes an echo path to generate an echo signal. An echo calibration circuit performs mapping according to codeword offset tables and performs processing according to response coefficients on the odd and the even parts to generate an echo-canceling calibration signal. A calibration parameter calculation circuit generates offsets according to an error signal of between the echo signal and the echo-canceling calibration signal and path information related to the echo calibration signal. The echo calibration circuit sets initial values to converge the response coefficients according to the error signal and updates the codeword offset tables according to the offsets.

### BACKGROUND OF THE INVENTION

### 1. Field of the Invention

The present invention relates to a digital-to-analog conversion apparatus and a digital-to-analog conversion method having a signal calibration mechanism.

### 2. Description of Related Art

A digital-to-analog conversion apparatus is an important circuit component to convert a signal from a digital form to an analog form. The digital-to-analog conversion apparatus multiplies different digital codes by corresponding conversion gain values to generate analog signals having different intensities.

However, an error is generated in the digital-to-analog conversion apparatus due to offsets of current sources therein. Further, an echo is generated due to the mismatch of a transmission path that transmits the signal. Different calibration technologies are required for the digital-to-analog conversion apparatus to perform calibration on the input signal and the output signal to accomplish a better conversion result.

### SUMMARY OF THE INVENTION

In consideration of the problem of the prior art, an object of the present invention is to supply a digital-to-analog conversion apparatus and a digital-to-analog conversion method having a signal calibration mechanism.

The present invention discloses a digital-to-analog conversion apparatus having a signal calibration mechanism that includes a digital-to-analog conversion circuit, an echo transmission circuit, an echo calibration circuit and a calibration parameter calculation circuit. The digital-to-analog conversion circuit includes a plurality of current sources operating under a first frequency to perform digital-to-analog conversion according to a signal feeding related to an input digital signal having a set of input codeword to generate an output analog signal to an echo path, wherein the signal feeding includes an odd part and an even part, the odd part including a round-off error. The echo transmission circuit performs signal processing that includes down-sampling on the echo path to generate an echo signal having a second frequency, wherein the second frequency is ½ of the first frequency. The echo calibration circuit operates under the second frequency to perform mapping according to a plurality of groups of offset tables and perform processing according to at least one group of response coefficients according to the odd part and the even part to generate at least one echo-cancelling calibration signal. The calibration parameter calculation circuit operates under the second frequency to generate a plurality of offsets according to an error signal between the echo signal and the echo-cancelling calibration signal and path information related to the echo calibration circuit, wherein the echo calibration circuit configures an initial value for the at least one group of response coefficients to make the at least one group of response coefficients converge according to the error signal and update the plurality of offset tables according to the offsets.

The present invention also discloses a digital-to-analog conversion method having a signal calibration mechanism that includes steps outlined below. Digital-to-analog conversion is performed by a digital-to-analog conversion circuit including a plurality of current sources operating under a first frequency according to a signal feeding related to an input digital signal having a set of input codeword to generate an output analog signal to an echo path, wherein the signal feeding includes an odd part and an even part, the odd part including a round-off error. Signal processing that includes down-sampling is performed on the echo path by an echo transmission circuit to generate an echo signal having a second frequency, wherein the second frequency is ½ of the first frequency. Mapping is performed according to a plurality of groups of offset tables and processing is performed according to at least one group of response coefficients according to the odd part and the even part by an echo calibration circuit operating under the second frequency to generate at least one echo-cancelling calibration signal. A plurality of offsets are generated according to an error signal between the echo signal and the echo-cancelling calibration signal and path information related to the echo calibration circuit by a calibration parameter calculation circuit operating under the second frequency, wherein the echo calibration circuit configures an initial value for the at least one group of response coefficients to make the at least one group of response coefficients converge according to the error signal and update the plurality of offset tables according to the offsets.

These and other objectives of the present invention will no doubt become obvious to those of ordinary skill in the art behind reading the following detailed description of the preferred embodiments that are illustrated in the various figures and drawings.

### BRIEF DESCRIPTION OF THE DRAWINGS

FIG. 1 illustrates a block diagram of a digital-to-analog conversion apparatus having a signal calibration mechanism according to an embodiment of the present invention.

FIG. 2 illustrates a detailed block diagram of the signal input circuit according to an embodiment of the present invention.

FIG. 3 illustrates a detailed block diagram of the echo calibration circuit according to an embodiment of the present invention.

FIG. 4 illustrates a block diagram of the remained echo-canceling circuit according to an embodiment of the present invention.

FIG. 5 illustrates a block diagram of the echo calibration circuit according to an embodiment of the present invention.

FIG. 6 illustrates a block diagram of the remained echo-canceling circuit according to an embodiment of the present invention.

FIG. 7 illustrates a flow chart of a digital-to-analog conversion method having a signal calibration mechanism according to an embodiment of the present invention.

### DETAILED DESCRIPTION OF THE PREFERRED EMBODIMENTS

An aspect of the present invention is to provide a digital-to-analog conversion apparatus and a digital-to-analog conversion method having a signal calibration mechanism to perform filtering and perform feeding of a round-off error on an input digital signal such that a calibration can be accomplished according to an echo signal without additionally generating a pseudo noise.

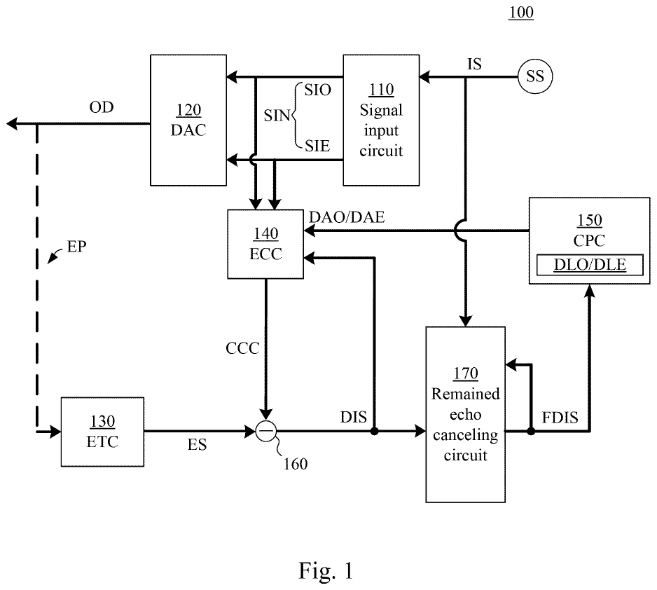

Reference is now made to FIG. 1. FIG. 1 illustrates a block diagram of a digital-to-analog conversion apparatus 100 having a signal calibration mechanism according to an embodiment of the present invention. The digital-to-analog conversion apparatus 100 includes a signal input circuit 110, a digital-to-analog conversion circuit 120 (abbreviated as DAC in FIG. 1), an echo transmission circuit 130 (abbreviated as ETC in FIG. 1), an echo calibration circuit 140 (abbreviated as ECC in FIG. 1) and a calibration parameter calculation circuit 150 (abbreviated as CPC in FIG. 1).

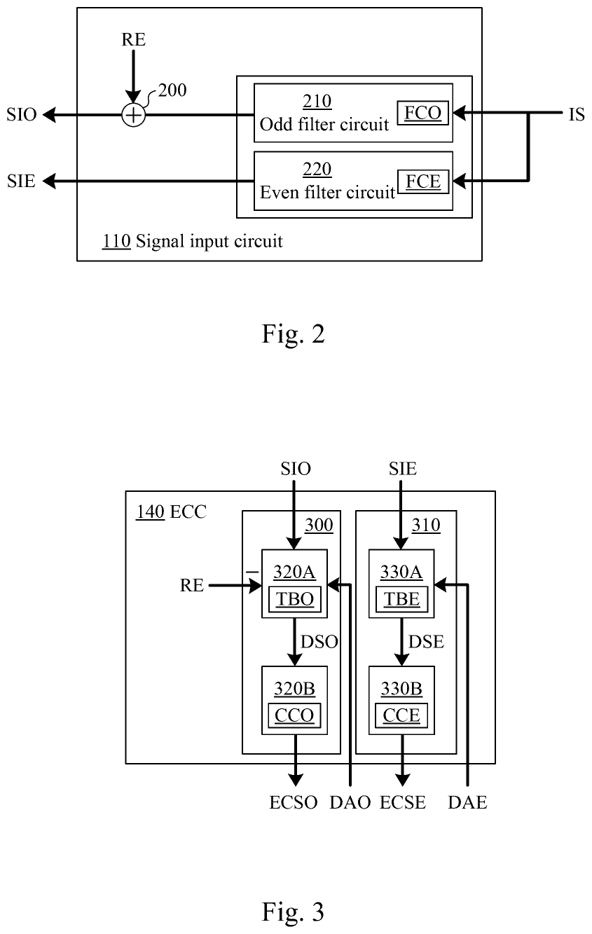

The signal input circuit 110 performs a transmission of a signal feeding SIN on the digital-to-analog conversion circuit 120. FIG. 2 illustrates a detailed block diagram of the signal input circuit 110 according to an embodiment of the present invention. The signal input circuit 110 includes a round-off error calculation circuit 200, an odd filter circuit 210 and an even filter circuit 220.

In an embodiment, the odd filter circuit 210 and the even filter circuit 220 receive an input digital signal IS from a signal source SS illustrated in FIG. 1, in which the signal source SS may be, for example, a transmitter (TX) in a communication system.

The odd filter circuit 210 performs filtering on the input digital signal according to a group of odd filtering coefficients FCO and a round-off error RE is added to the filtered input digital signal IS by the round-off error calculation circuit 200 to generate the odd part SIO of the signal feeding SIN, wherein the group odd filtering coefficients FCO include a decimal part. In an embodiment, the group odd filtering coefficients FCO is in the form of such as, but not limited to [0.5 0.5].

Under such a condition, when the input digital signal IS is a 8-bit signal and the signal that the digital-to-analog conversion circuit 120 is able to process is also 8-bit, the signal generated based on the processing of the odd filter circuit 210 may have 9 bits due to an additional least significant bit (LSB) generated due to the decimal part of the group odd filtering coefficients FCO. As a result, the round-off error calculation circuit 200 removes the least significant bit to generate the odd part SIO by performing round down (by adding the round-off error RE that is a negative value) or round up (by adding the round-off error RE that is a positive value) on the signal generated by the odd filter circuit 210 according to the round-off error RE. The odd part SIO thus becomes a 8-bit signal that the digital-to-analog conversion circuit 120 is able to process.

The even filter circuit 220 performs filtering on the input digital signal IS according to a group of even filtering coefficients FCE to generate an even part SIE of the signal feeding SIN, wherein the group even filtering coefficients FCE do not include the decimal part. In an embodiment, the group even filtering coefficients FCE is in the form of such as, but not limited to [1.0 0.0]. Since the group even filtering coefficients FCE do not include the decimal part, the even part SIE still has 8 bits when the input digital signal IS is a 8-bit signal.

The digital-to-analog conversion circuit 120 includes a plurality of current sources (not illustrated in the figure) operating under a first frequency, wherein first frequency is such as, but not limited to 800 MHz. The digital-to-analog conversion circuit 120 performs digital-to-analog conversion according to the signal feeding related to the input digital signal IS having a set of input codeword to generate an output analog signal OD.

As a result, the input digital signal IS may be operated under a second frequency and become the signal feeding SIN, after being processed by the signal input circuit 110, having the first frequency that is able to be processed by the digital-to-analog conversion circuit 120, such that the digital-to-analog conversion circuit 120 generates the output analog signal OD having the first frequency accordingly. The value of the second frequency is around ½ of the value of the first frequency. In the numerical example described above, when the first frequency is 800 MHz, the second frequency is 400 MHz.

The output analog signal OD is a signal that is actually transmitted to an external terminal. However, the output analog signal OD may be leaked to such as, but not limited to a receiver (RX, not illustrated in the figure) through an echo path EP in FIG. 1. In an embodiment, a resistor (not illustrated in the figure) can be disposed on the echo path EP to divide the voltage thereon to perform echo-canceling.

The echo transmission circuit 130 in FIG. 1 performs signal processing tha includes down-sampling on the echo path EP to generate an echo signal ES having the second frequency. The signal processing may also include such as, but not limited to an echo response processing and an analog-to-digital conversion performed based on down-sampling to generate the echo signal ES.

The digital-to-analog conversion circuit 120 described above includes a plurality of current sources (not illustrated in the figure) to generate the analog signal according to the control of the corresponding signal feeding. The current sources include thermometer-controlled current sources and binary-controlled current sources. In an embodiment, the current sources include 15 thermometer-controlled current sources represented by T01~T15 and 4 binary-controlled current sources represented by B01~B04, each controlled by the input codeword to be electrically coupled to different voltage sources to output one of a positive voltage and a negative voltage. Each of the current sources described above has a current offset such that the analog signal includes a static mismatch error.

The echo calibration circuit 140 cancels the static mismatch error of each of the conversion circuits. More specifically, the echo calibration circuit 140 operates under the second frequency to perform mapping according to a plurality of groups of offset tables and perform processing according to at least one group of response coefficients according to according to the odd part SIO and the even part SIE to generate at least one echo-cancelling calibration signal CCC.

FIG. 3 illustrates a detailed block diagram of the echo calibration circuit 140 according to an embodiment of the present invention. The echo calibration circuit 140 includes an odd calibration circuit 300 and an even calibration circuit 310.

The odd calibration circuit 300 includes an odd mapping circuit 320A and an odd response circuit 320B. The odd mapping circuit 320A receives the odd part SIO, performs subtraction thereon according to the round-off error RE (in which a subtraction with a negative value when the round down is performed and a subtraction with a positive value when the round up is performed) and further performs mapping thereon according to an odd offset table TBO of the offset tables to generate an odd mapping signal DSO. The odd response circuit 320B receives the odd mapping signal DSO to perform processing thereon according to a group of odd response coefficients CCO of the response coefficients to generate an odd calibration signal ESCO included by the echo-cancelling calibration signal CCC.

The even calibration circuit 310 includes an even mapping circuit 330A and an even response circuit 330B. The even mapping circuit 330A receives the even part SIE and further performs mapping thereon according to an even offset table TBE of the offset tables to generate an even mapping signal DSE. The even response circuit 330B receives the even mapping signal DSE to perform processing thereon according to a group of even response coefficients CCE of the response coefficients to generate an even calibration signal ESCE included by the echo-cancelling calibration signal CCC.

In the mapping circuits described above, each of the offset tables includes a plurality of one-to-one corresponding relations between a plurality of codewords and a plurality of codeword offset values. The input codeword corresponds to one of the codewords in each of the offset tables.

In an embodiment, the digital-to-analog conversion apparatus 100 in FIG. 1 may further include an error calculation circuit 160 to calculate an error signal DIS between the echo signal ES and the calibration signals (i.e., the odd calibration signal ESCO and the even calibration signal ESCE) described above.

In an embodiment, the digital-to-analog conversion apparatus 100 in FIG. 1 further includes a remained echo-canceling circuit 170 to further cancel the remained echo.

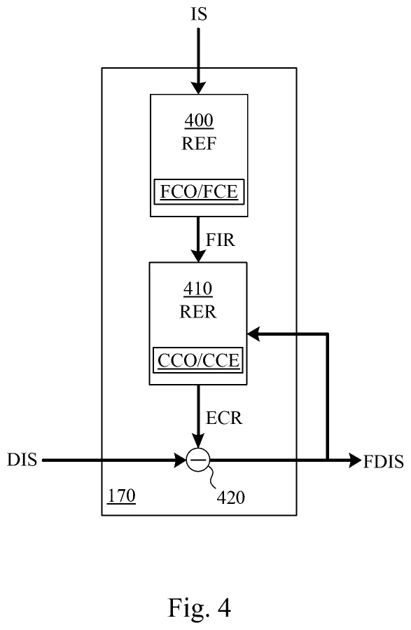

Reference is now made to FIG. 4. FIG. 4 illustrates a block diagram of t remained echo-canceling circuit 170 according to an embodiment of the present invention. The remained echo-canceling circuit 170 includes a remained echo filter circuit 400 (abbreviated as REF in FIG. 4), a remained echo response circuit 410 (abbreviated as RER in FIG. 4) and a canceling circuit 420.

The remained echo filter circuit 400 receives the input digital signal IS and performs filtering according to the group odd filtering coefficients FCO and the group even filtering coefficients FCE to generate a filtered result FIR. The remained echo response circuit 410 receives the filtered result FIR to perform processing thereon according to the group odd response coefficients CCO and the group even response coefficients CCE to generate a remained echo-cancelling signal ECR.

The canceling circuit 420 subtracts the error signal DIS from the remained echo-cancelling signal ECR to generate a final error signal FDIS.

The calibration parameter calculation circuit 150 generates a plurality of offsets according to the error signal DIS between the echo signal ES and the calibration signals (i.e., the odd calibration signal ESCO and the even calibration signal ESCE) described above and the path information related to the echo calibration circuit 140. In an embodiment, the calibration parameter calculation circuit 150 substantially generates the offsets according to the final error signal FDIS processed by the remained echo-canceling circuit 170.

In an embodiment, the path information includes the path delays DLO and DLE from each of the response circuits (i.e., the odd response circuit 320B and the even response circuit 330B to the calibration parameter calculation circuit 150. Since the processing of these circuits takes time, the calibration parameter calculation circuit 150 needs to trace the calculated offsets back to the corresponding input codeword according to the path delays DLO and DLE.

In an embodiment, the calibration parameter calculation circuit 150 receives the odd response coefficients CCO and the even response coefficients CCE of the odd response circuit 320B and the even response circuit 330B, performs one-dimensional inversion respectively on these response coefficients, multiplies the values of the final error signal FDIS by the inversed response coefficients and accumulates the multiplication results to generate corresponding inverted offsets values. The calibration parameter calculation circuit 150 further set the inverted offsets values to be the odd offsets DAO and the even offsets DAE corresponding to the odd mapping circuit 320A and the even mapping circuit 330A according to the path delays DLO and DLE.

It is appreciated that, the generation of the offsets described above is merely an example. In other embodiments, the calibration parameter calculation circuit 150 may generate the offsets by using other methods.

Since the content of the input digital signal IS and the content of the odd mapping signal DSO and the even mapping signal DSE generated by performing mapping based on the static mismatch are not related, the characteristic of a pseudo noise is presented such that the echo calibration circuit 140 is able to set an initial value for each group of the response coefficients to perform training according to the final error signal FDIS without feeding an additional pseudo noise to converge each group of the response coefficients. The calibration can therefore be performed on the digital-to-analog conversion circuit 120.

For example, the echo calibration circuit 140 may set a part of the coefficients in the odd response coefficients CCO and the group even response coefficients CCE to be 1 as the initial values and set other coefficients to be 0 to perform training.

When each group of the response coefficients converge, the echo calibration circuit 140 updates the offset tables that include the odd offset table TBO and the even offset table TBE according to the odd offsets DAO and the even offsets DAE.

The signals used to perform echo-cancelling described above are generated based on the processing of the echo calibration circuit 140 and the remained echo-canceling circuit 170. The processing of the echo calibration circuit 140 and the remained echo-canceling circuit 170 is thus expressed by:

$$IS conv ECHO + TBE conv CCE + ( RE + TBO ) con CCO \qquad ( equation 1 )$$

The term “conv” represents the convolution operation. The term “ECHO” is the processing performed by the remained echo filter circuit 400 and the remained echo response circuit 410 and is expressed by:

$$ECHO = FCE conv CCE + FCO conv CCO \qquad ( equation 2 )$$

Since no additional pseudo noise is fed, an interaction of the gain is presented in each pair of the mapping circuit and the response circuit in the echo calibration circuit 140 such that the convergence is more difficult to be accomplished. However, by adding the round-off error RE, the amount of the gain can be fixed to prevent the occurrence of overflow

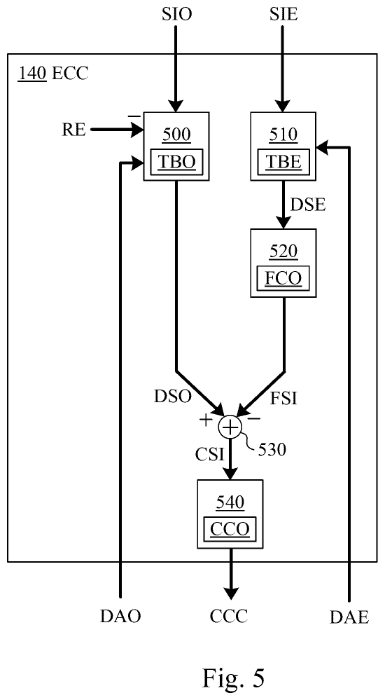

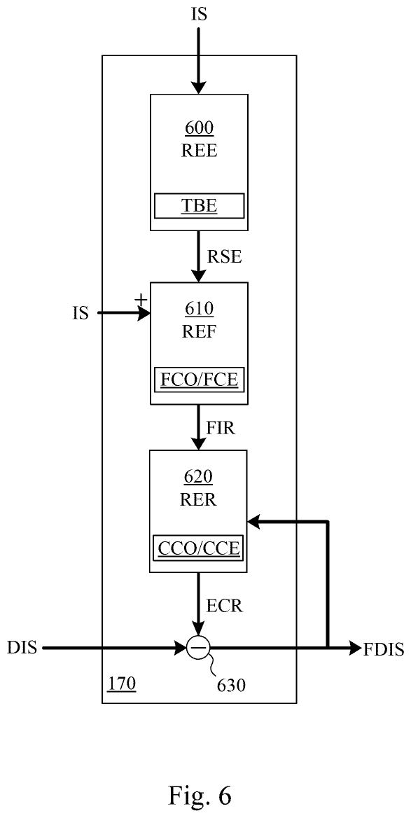

In another embodiment, by performing the mathematic derivation based on (equation 1), the digital-to-analog conversion apparatus 100 may adjust the configuration of the echo calibration circuit 140 and remained echo-canceling circuit 170. The echo calibration circuit 140 and the remained echo-canceling circuit 170 having the configuration being adjusted are described in the following paragraphs in accompany with FIG. 5 and FIG. 6.

Reference is now made to FIG. 5. FIG. 5 illustrates a block diagram of the echo calibration circuit 140 according to an embodiment of the present invention. In the present embodiment, the echo calibration circuit 140 an odd mapping circuit 500, an even mapping circuit 510, an odd filter circuit 520, a merging circuit 530 and an odd response circuit 540.

The odd mapping circuit 500 receives the odd part SIO, performs subtraction thereon according to the round-off error RE and performs mapping thereon according to the odd offset table TBO of offset tables to generate the odd mapping signal DSO. The even mapping circuit 510 receives the even part SIE and performs mapping thereon according to the even offset table TBE to generate the even mapping signal DSE.

The odd filter circuit 520 performs filtering on the even mapping signal DSE according to the group odd filtering coefficients FCO to generate a filtered signal FSI. Comparing to the even mapping signal DSE, the filtered signal FSI has a higher chance to include an additional least significant bit since the group odd filtering coefficients FCO have the decimal part. However, the echo calibration circuit 140 operates in a fully digital domain. The round down or round up operation performed by the round-off error calculation circuit 200 for the feeding of the processed result generated by the odd filter circuit 210 to the digital-to-analog conversion circuit 120 is therefore not required during the generation of the filtered signal FSI.

The merging circuit 530 performs subtraction on the odd mapping signal DSO and filtered signal FSI to generate a merged signal CSI.

The odd response circuit 540 receives the merged signal CSI and performs processing thereon according to a group of odd response coefficients CCO to generate the echo-cancelling calibration signal CCC.

Reference is now made to FIG. 6. FIG. 6 illustrates a block diagram of the remained echo-canceling circuit 170 according to an embodiment of the present invention. In the present embodiment, the remained echo-canceling circuit 170 includes a remained echo even mapping circuit 600 (abbreviated as REE in FIG. 6), a remained echo filter circuit 610 (abbreviated as REF in FIG. 6), a remained echo response circuit 620 (abbreviated as RER in FIG. 6) and a canceling circuit 630.

The remained echo even mapping circuit 600 receives the input digital signal IS and performs mapping thereon according to the even offset table TBE to generate the remained echo even mapping signal RSE.

The remained echo filter circuit 610 receives the input digital signal IS and the remained echo even mapping signal RSE and performs filtering thereon according to the group odd filtering coefficients FCO and the group even filtering coefficients FCE to generate the filtered result FIR.

The remained echo response circuit 620 receives the filtered result FIR and performs processing thereon according to the group odd response coefficients CCO and the group even response coefficients CCE to generate a remained echo-cancelling signal ECR.

The canceling circuit 630 subtracts the error signal DIS from the remained echo-cancelling signal ECR to generate the final error signal FDIS.

The processing of the calibration parameter calculation circuit 150 performed in response to the echo calibration circuit 140 and remained echo-canceling circuit 170 in the embodiment corresponding to FIG. 5 and FIG. 6 is identical to the processing performed in response to the embodiment corresponding to FIG. 3 and FIG. 4. The detail is not described herein.

Similarly, since no additional pseudo noise is fed, an interaction of the gain is presented in each pair of the mapping circuit and the response circuit. However, the gain of the remained echo-canceling circuit 170 is fixed. As a result, the gain of the even offset table TBE disposed in the remained echo-canceling circuit 170 in the present embodiment can also be fixed. The gains of the other offset tables and the response coefficients can be further fixed to prevent the occurrence of overflow.

The signals used to perform echo-cancelling described above are generated based on the processing of the echo calibration circuit 140 and the remained echo-canceling circuit 170. The processing of the echo calibration circuit 140 and the remained echo-canceling circuit 170 is thus expressed by:

$$( IS + TBE ) conv ECHO + ( RE + TBO - TBE conv FCO ) conv CCO \qquad ( equation 3 )$$

Since the term “ECHO” is the processing performed by the remained echo filter circuit 400 and the remained echo response circuit 410 and is expressed by (equation 2), (equation 3) can be further modified to become:

$$( IS + TBE ) conv FCE conv CCE + ( IS + TBE ) conv FCO conv CCO + ( RE + TBO - TBE conv FCO ) conv CCO \qquad ( equation 4 )$$

After simplification is performed, (equation 4) is equivalent to (equation 1 In other words, the processing performed by the echo calibration circuit 140 and remained echo-canceling circuit 170 in FIG. 5 and FIG. 6 is equivalent to the processing performed by the echo calibration circuit 140 and remained echo-canceling circuit 170 in FIG. 3 and FIG. 4.

As a result, the digital-to-analog conversion apparatus of the present invention performs filtering and performs feeding of a round-off error on an input digital signal such that a calibration can be accomplished according to an echo signal without additionally generating a pseudo noise.

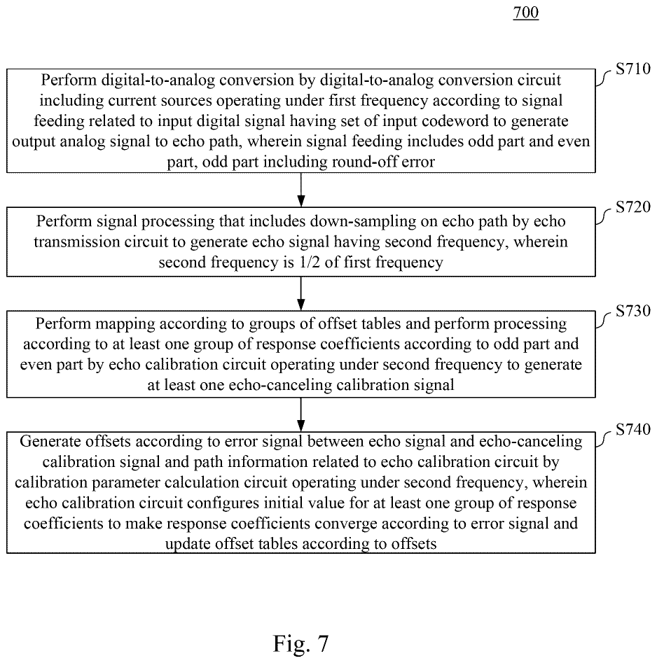

Reference is now made to FIG. 7. FIG. 7 illustrates a flow chart of a digital-to-analog conversion method 700 having a signal calibration mechanism according to an embodiment of the present invention.

In addition to the apparatus described above, the present disclosure further provides the digital-to-analog conversion method 700 having the signal calibration mechanism that can be used in such as, but not limited to, the digital-to-analog conversion apparatus 100 in FIG. 1. As illustrated in FIG. 7, an embodiment of the digital-to-analog conversion method 700 includes the following steps.

In step S710, digital-to-analog conversion is performed by the digital-to-analog conversion circuit 120 including the current sources operating under the first frequency according to the signal feeding SIN related to the input digital signal IS having the set of input codeword to generate the output analog signal OD to the echo path, wherein the signal feeding SIN includes the odd part SIO and the even part SIE, the odd part SIO including the round-off error RE.

In step S720, signal processing that includes down-sampling is performed on the echo path EP by the echo transmission circuit 130 to generate the echo signal ES having the second frequency, wherein the second frequency is ½ of the first frequency.

In step S730, mapping is performed according to the groups of offset tables and processing is performed according to the at least one group of response coefficients according to the odd part SIO and the even part SIE by the echo calibration circuit 140 operating under the second frequency to generate the at least one echo-cancelling calibration signal CCC.

In step S740, the offsets are generated according to the error signal DIS between the echo signal ES and the echo-cancelling calibration signal CCC and the path information related to the echo calibration circuit 140 by the calibration parameter calculation circuit 150 operating under the second frequency, wherein the echo calibration circuit 140 configures the initial value for the at least one group of response coefficients to make the at least one group of response coefficients converge according to the error signal DIS and update the plurality of offset tables according to the offsets.

It is appreciated that the embodiments described above are merely an example. In other embodiments, it should be appreciated that many modifications and changes may be made by those of ordinary skill in the art without departing, from the spirit of the disclosure.

In summary, the present invention discloses the digital-to-analog conversion apparatus and the digital-to-analog conversion method having the signal calibration mechanism to perform filtering and perform feeding of a round-off error on an input digital signal such that a calibration can be accomplished according to an echo signal without additionally generating a pseudo noise.

The aforementioned descriptions represent merely the preferred embodiment of the present invention, without any intention to limit the scope of the present invention thereto. Various equivalent changes, alterations, or modifications based on the claims of present invention are all consequently viewed as being embraced by the scope of the present invention.

What is claimed is:

1. A digital-to-analog conversion apparatus having a signal calibration mechanism, comprising:
a digital-to-analog conversion circuit comprising a plurality of current sources operating under a first frequency to perform digital-to-analog conversion according to a signal feeding related to an input digital signal having a set of input codeword to generate an output analog signal to an echo path, wherein the signal feeding comprises an odd part and an even part, the odd part comprising a round-off error;
an echo transmission circuit to perform signal processing that comprises down-sampling on the echo path to generate an echo signal having a second frequency, wherein the second frequency is ½ of the first frequency;
an echo calibration circuit operating under the second frequency to perform mapping according to a plurality of groups of offset tables and perform processing according to at least one group of response coefficients according to the odd part and the even part to generate at least one echo-cancelling calibration signal; and
a calibration parameter calculation circuit operating under the second frequency to generate a plurality of offsets according to an error signal between the echo signal and the echo-cancelling calibration signal and path information related to the echo calibration circuit, wherein the echo calibration circuit configures an initial value for the at least one group of response coefficients to make the at least one group of response coefficients converge according to the error signal and update the plurality of offset tables according to the offsets.

2. The digital-to-analog conversion apparatus of claim 1, further comprising a signal input circuit to perform signal feeding on the digital-to-analog conversion circuit, the signal input circuit comprising:
a round-off error calculation circuit;
an odd filter circuit to perform filtering on the input digital signal according to a group of odd filtering coefficients and add the round-off error thereto by using the round-off error calculation circuit to generate the odd part of the signal feeding, wherein the group of odd filtering coefficients comprise a decimal part; and
an even filter circuit to perform filtering on the input digital signal according to a group of even filtering coefficients to generate the even part of the signal feeding, wherein the group of even filtering coefficients do not comprise the decimal part.

3. The digital-to-analog conversion apparatus of claim 1, wherein the echo calibration circuit comprises:
an odd calibration circuit comprising:
an odd mapping circuit to receive the odd part, perform subtraction thereon according to the round-off error and further perform mapping thereon according to an odd offset table of the offset tables to generate an odd mapping signal;
an odd response circuit to receive the odd mapping signal to perform processing thereon according to a group of odd response coefficients of the at least one group of response coefficients to generate an odd calibration signal comprised by the at least one echo-cancelling calibration signal; and
an even calibration circuit comprising:
an even mapping circuit to receive the even part and further perform mapping thereon according to an even offset table of the offset tables to generate an even mapping signal; and
an even response circuit to receive the even mapping signal to perform processing thereon according to a group of even response coefficients of the at least one group of response coefficients to generate an even calibration signal comprised by the at least one echo-cancelling calibration signal.

4. The digital-to-analog conversion apparatus of claim 3, further comprising a remained echo-canceling circuit, the remained echo-canceling circuit comprising:
a remained echo filter circuit to receive the input digital signal and perform filtering thereon according to the group odd filtering coefficients and the group even filtering coefficients to generate a filtered result;
a remained echo response circuit to receive the filtered result to perform processing thereon according to the group odd response coefficients and the group even response coefficients to generate a remained echo-cancelling signal; and
a canceling circuit to subtract the error signal from the remained echo-cancelling signal to generate a final error signal;
wherein the calibration parameter calculation circuit substantially converges the at least one group of response coefficients according to the final error signal and generates the offsets according to the final error signal and the path information related to the echo calibration circuit.

5. The digital-to-analog conversion apparatus of claim 1, wherein the echo calibration circuit comprises:
an odd mapping circuit to receive the odd part, perform subtraction thereon according to the round-off error and perform mapping thereon according to an odd offset table of the offset tables to generate an odd mapping signal;
an even mapping circuit to receive the even part and perform mapping thereon according to an even offset table of the offset tables to generate an even mapping signal;
an odd filter circuit to perform filtering on the even mapping signal according to the group odd filtering coefficients to generate a filtered signal;
a merging circuit to perform subtraction on the odd mapping signal and the filtered signal to generate a merged signal; and
an odd response circuit to receive the merged signal and perform processing thereon according to a group of odd response coefficients to generate the at least one echo-cancelling calibration signal.

6. The digital-to-analog conversion apparatus of claim 5, further comprising a remained echo-canceling circuit, the remained echo-canceling circuit comprising:
a remained echo even mapping circuit to receive the input digital signal and perform mapping thereon according to the even offset table to generate a remained echo even mapping signal;
a remained echo filter circuit to receive the input digital signal and the remained echo even mapping signal and perform filtering thereon according to the group odd filtering coefficients and the group even filtering coefficients to generate a filtered result;
a remained echo response circuit to receive the filtered result and perform processing thereon according to the group odd response coefficients and a group of even response coefficients to generate a remained echo-cancelling signal; and
a canceling circuit to subtract an error signal between the echo-cancelling calibration signal and the echo signal from the remained echo-cancelling signal to generate a final error signal;
wherein the calibration parameter calculation circuit substantially converges the at least one group of response coefficients according to the final error signal and generates the offsets according to the final error signal and the path information related to the echo calibration circuit.

7. A digital-to-analog conversion method having a signal calibration mechanism, comprising:
performing digital-to-analog conversion by a digital-to-analog conversion circuit comprising a plurality of current sources operating under a first frequency according to a signal feeding related to an input digital signal having a set of input codeword to generate an output analog signal to an echo path, wherein the signal feeding comprises an odd part and an even part, the odd part comprising a round-off error;
performing signal processing that comprises down-sampling on the echo path by an echo transmission circuit to generate an echo signal having a second frequency, wherein the second frequency is ½ of the first frequency;
performing mapping according to a plurality of groups of offset tables and performing processing according to at least one group of response coefficients according to the odd part and the even part by an echo calibration circuit operating under the second frequency to generate at least one echo-cancelling calibration signal; and
generating a plurality of offsets according to an error signal between the echo signal and the echo-cancelling calibration signal and path information related to the echo calibration circuit by a calibration parameter calculation circuit operating under the second frequency, wherein the echo calibration circuit configures an initial value for the at least one group of response coefficients to make the at least one group of response coefficients converge according to the error signal and update the plurality of offset tables according to the offsets.

8. The digital-to-analog conversion method of claim 7, further comprising:
performing filtering on the input digital signal according to a group of odd filtering coefficients and adding the round-off error thereto by using a round-off error calculation circuit comprised by a signal input circuit by an odd filter circuit comprised by the signal input circuit to generate the odd part of the signal feeding, wherein the signal input circuit is to perform signal feeding on the digital-to-analog conversion circuit and the group of odd filtering coefficients comprise a decimal part; and
performing filtering on the input digital signal according to a group of even filtering coefficients by an even filter circuit comprised by the signal input circuit to generate the even part of the signal feeding, wherein the group of even filtering coefficients do not comprise the decimal part.

9. The digital-to-analog conversion method of claim 8, further comprising:
receiving the odd part, removing the round-off error therefrom and further performing mapping thereon according to an odd offset table of the offset tables by an odd mapping circuit comprised by an odd calibration circuit comprised by the echo calibration circuit to generate an odd mapping signal;
receiving the odd mapping signal to perform processing thereon according to a group of odd response coefficients of the at least one group of response coefficients by an odd response circuit comprised by the odd calibration circuit to generate an odd calibration signal comprised by the at least one echo-cancelling calibration signal;
receiving the even part and further performing mapping thereon according to an even offset table of the offset tables by an even mapping circuit comprised by an even calibration circuit comprised by the echo calibration circuit to generate an even mapping signal; and
receiving the even mapping signal to perform processing thereon according to a group of even response coefficients of the at least one group of response coefficients by an even response circuit comprised by the even calibration circuit to generate an even calibration signal comprised by the at least one echo-cancelling calibration signal.

10. The digital-to-analog conversion method of claim 9, further comprising:
receiving the input digital signal and performing filtering thereon according to the group odd filtering coefficients and the group even filtering coefficients by a remained echo filter circuit comprised by a remained echo-canceling circuit to generate a filtered result;
receiving the filtered result to perform processing thereon according to the group odd response coefficients and the group even response coefficients by a remained echo response circuit comprised by the remained echo-canceling circuit to generate a remained echo-cancelling signal; and
subtracting the error signal from the remained echo-cancelling signal by a canceling circuit comprised by the remained echo-canceling circuit to generate a final error signal;
wherein the calibration parameter calculation circuit substantially converges the at least one group of response coefficients according to the final error signal and generates the offsets according to the final error signal and the path information related to the echo calibration circuit.

11. The digital-to-analog conversion method of claim 7, further comprising:
receiving the odd part, removing the round-off error therefrom and performing mapping thereon according to an odd offset table of the offset tables by an odd mapping circuit comprised by the echo calibration circuit to generate an odd mapping signal;
receiving the even part and performing mapping thereon according to an even offset table of the offset tables by an even mapping circuit comprised by the echo calibration circuit to generate an even mapping signal;
performing filtering on the even mapping signal according to the group odd filtering coefficients by an odd filter circuit comprised by the echo calibration circuit to generate a filtered signal;
performing subtraction on the odd mapping signal and the filtered signal by a merging circuit comprised by the echo calibration circuit to generate a merged signal; and
receiving the merged signal and performing processing thereon according to a group of odd response coefficients by an odd response circuit comprised by the echo calibration circuit to generate the at least one echo-cancelling calibration signal.

12. The digital-to-analog conversion method of claim 11, further comprising:
receiving the input digital signal and performing mapping thereon according to the even offset table by a remained echo even mapping circuit comprised by a remained echo-canceling circuit to generate a remained echo even mapping signal;
receiving the input digital signal and the remained echo even mapping signal and performing filtering thereon according to the group odd filtering coefficients and the group even filtering coefficients by a remained echo filter circuit comprised by the remained echo-canceling circuit to generate a filtered result;
receiving the filtered result and performing processing thereon according to the group odd response coefficients and a group of even response coefficients by a remained echo response circuit comprised by the remained echo-canceling circuit to generate a remained echo-cancelling signal; and
subtracting an error signal between the echo-cancelling calibration signal and the echo signal from the remained echo-cancelling signal by a canceling circuit comprised by the remained echo-canceling circuit to generate a final error signal;
wherein the calibration parameter calculation circuit substantially converges the at least one group of response coefficients according to the final error signal and generates the offsets according to the final error signal and the path information related to the echo calibration circuit.
